(19) United States
(12) Patent Application Publication
(10) Pub. No.: US 2023/0287555 A1
(43) Pub. Date: Sep. 14, 2023

(54) MICRO-ELECTROMECHANICAL SYSTEM (MEMS) BASED INERTIAL SENSOR AND METHOD OF FABRICATION THEREOF

(71) Applicant: Abdulilah Mayet, Jeddah (SA)

(72) Inventor: Abdulilah Mayet, Jeddah (SA)

(21) Appl. No.: 18/109,385

(22) Filed: Feb. 14, 2023

Related U.S. Application Data
(60) Provisional application No. 63/318,405, filed on Mar. 10, 2022.

(51) Int. Cl. C23C 14/06; B81C 99/00; C23C 14/34; C23C 14/54

(52) U.S. Cl. CPC C23C 14/0641; B81C 99/0025; C23C 14/3407; C23C 14/54

(57) ABSTRACT

A system for fabricating a crystalline film is provided comprising a sputtering chamber that receives placement of a substrate, receives placement of a Tungsten target, and receives configuration of a separation distance between the substrate and the Tungsten target. The system also receives adjustment of chamber pressure, receives selection of a gas mixture ratio, and receives selection of a sputtering power profile. The chamber yields crystalline cluster-free amorphous Tungsten nitride alloy film. The chamber receives placement of the Tungsten target on a sputtering tool. The separation distance is configured to minimize adatom mobility of film produced. The chamber pressure is adjusted within a range of about 30 mTorr to about 5 mTorr, inclusive. The gas mixture ratio is a sputtering gas mixture ratio of Argon to Nitrogen. The sputtering power profile is for the sputtering tool. The power profile is 300 W of alternating current.

### CROSS REFERENCE TO RELATED APPLICATIONS

The present non-provisional patent application is related to U.S. Provisional Patent Application No. 63/318,405 filed Mar. 10, 2022, the contents of which are incorporated herein in their entirety.

### FIELD OF THE DISCLOSURE

The present disclosure relates to micro-electromechanical system structures and to inertial sensors. More particularly, the present disclosure relates to capacitive micro-electromechanical system (MEMS)-based inertial sensors and methods of fabrication thereof.

### BACKGROUND

Inertial sensors are sensors based on inertia and relevant measuring principles. Inertial sensors range from microelectromechanical systems (MEMS) inertial sensors, which may measure only a few μm, up to ring laser gyroscopes that are high-precision devices with a size of up to 50 cm. Inertial sensors may be important to navigation, motion, and autonomous navigation of unmanned aircraft. Inertial sensors for aerial robotics may take the form of inertial measurement units (IMU) which comprise accelerometers, gyroscopes, inclinometer, and magnetometers.

MEMS-based inertial sensors may range from consumer to tactical grade. Consumer-grade inertial sensors may be made of polysilicon sensing which may be compatible with complementary metal-oxide semiconductor (CMOS) fabrication processes but utilizes low-grade material. Thus, the performance of such inertial sensors is poor.

Tactical and navigation grade inertial sensors, by contrast, are made of single-crystalline silicon using a silicon on insulator (SOI) wafer. Fabrication processes for this grade of sensors may be complicated and require a specialized facilities to fabricate the inertial sensor as a standalone part connected to a readout integrated circuit (ROIC) by wire bonding, which further increases the cost of the inertial sensors.

### BRIEF DESCRIPTION OF THE FIGURES

FIG. 1A is a diagram of a side view of a MEMS-based inertial sensor in accordance with an embodiment of the present disclosure.

FIG. 1B is a diagram of a top view of an exemplary MEMS based inertial sensor in accordance with an embodiment of the present disclosure.

FIG. 2 is a diagram of an exemplary process of fabricating a crystalline cluster-free inorganic compound comprising α-WNx (amorphous tungsten nitride) film in accordance with an embodiment of the present disclosure.

FIG. 3 is a diagram of an exemplary representation of a MEMS gyroscope in accordance with an embodiment of the present disclosure.

FIG. 4A is a diagram of a Piezoelectric accelerometer in accordance with an embodiment of the present disclosure.

FIG. 4B illustrate exemplary representations of MEMS accelerometer with sensitivity axis along X-axis in accordance with an embodiment of the present invention.

### DETAILED DESCRIPTION

Systems and methods described herein provide a MEMS-based inertial sensor based on CMOS (complementary metal-oxide semiconductor) compatible methods of fabrication that overcome at least the limitations described above. The present disclosure provides methods of fabrication of MEMS-based inertial sensors characterized by high inertia force, retaining force and spring constant, longer lifetime, low resistivity, and sensitivity for low and high ‘g’ values. The methods provided are in situ with CMOS-based read out integrated circuit (ROIC) fabrication.

Systems and methods provided herein are directed to improving performance of the inertial sensor by using materials with low electric resistance and high density. Young's modulus and hardness to inertial sensor detector are characteristics which may lead to high sensitivity. MEMS-based inertial sensors provided herein may be compatible with CMOS fabrication processes, allowing the complete sensor to be fabricated in a single fabrication process on top of the ROIC.

The sensor provided herein includes a proof mass element that moves in response to a motion. A film of an inorganic compound such as α-WNx (amorphous tungsten nitride) coated acts as a detector. Amorphous tungsten nitride (α-WNx) metal film is provided for inertial sensor and manufacturing methods. The α-WNx material has properties with a high density of 17.5 g/cm³ which may boost its inertia force. Young's modulus (E) equals 300 GPa, which gives high retaining force and spring constant. Hardness (H) of 3 GPa provides a longer lifetime and very low resistivity as a metal equal to 200 μΩcm for high Q factor.

These combined properties make the α-WNx-based inertial sensor a high-quality sensor that may match tactical and navigation grade for a low noise value, stable and high reproducibility properties. The fully amorphous structure provides a robust operation with significantly reduced chance of fracture.

The deposition and micromachining process of the α-WNx is compatible with CMOS fabrication processes, allowing the complete sensor to be fabricated in a single fabrication process on top of ROIC part of silicon substrate separated with a sacrificial layer. After a release step, the film of inorganic compound such as α-WNx is dangled over the ROIC.

The inertial sensor further comprises electrodes coupled to the silicon substrate. This provides structural support for the dangling inorganic compound which is the α-WNx sensor and further provides electrical connectivity.

Systems and methods introduced herein further provide a crystalline cluster-free film of inorganic compound such as amorphous α-WNx Tungsten nitride alloy. The film is fabricated from a mixture of Tungsten metal atoms and inert gas mixture of Nitrogen and argon atoms. The mixture is deposited such that a crystalline cluster-free amorphous Tungsten nitride alloy film is created. The crystalline cluster-free amorphous Tungsten nitride alloy film retains its crystalline cluster-free amorphous structure at most temperatures.

The method includes sputtering a substrate using a Tungsten target. The method steps comprise placing a substrate in a sputtering chamber and placing an inorganic compound such as α-WNx (amorphous tungsten nitride) on a sputtering tool inside the sputtering chamber. The steps further comprise selecting a separation distance between the inorganic compound target and the maximized substrate. This action may minimize adsorbed atom mobility of the crystalline cluster-free inorganic compound film deposited due to sputtering.

The method steps further comprise adjusting a chamber pressure within an adequate range and adjusting sputtering gas mixture ratio. The sputtering gas mixture comprises inert gases such as of Argon and Nitrogen. The method steps may also comprise adjusting sputtering power of the sputtering tool of 300 W of alternating current.

The inertial sensor includes a proof mass element that moves in response to a motion. A film of an inorganic compound such as α-WNx (amorphous tungsten nitride) acts as a detector. Amorphous tungsten nitride (α-WNx) metal film is provided for an inertial sensor and a manufacturing method.

The α-WNx material has properties with a high density of 17.5 g/cm3, which boosts its inertia force. Young's modulus (E) equals 300 GPa, which gives high retaining force and spring constant. Hardness (H) of 3 GPa provides a longer lifetime and low resistivity as a metal equal to 200 μΩcm for high Q factor. These combined properties make the α-WNx-based inertial sensor a high-quality sensor that may match tactical and navigation grade for a low noise value and stable and high reproducibility properties. The amorphous structure provides a robust operation with minimal possibility of fractures.

The deposition and micromachining process of the α-WNx is compatible with CMOS fabrication processes, allowing the complete sensor to be fabricated in a single fabrication process on top of ROIC part of silicon substrate separated with a sacrificial layer.

After a release step, the film of inorganic compound such as α-WNx is dangled over the ROIC. The inertial sensor further comprises electrodes coupled to the silicon substrate providing structural support for the dangling inorganic compound which is the α-WNx sensor and further provides electrical connectivity.

Another aspect of the present disclosure provides a crystalline cluster-free film of inorganic compound such as amorphous α-WNx Tungsten nitride alloy. The film is fabricated from a mixture of Tungsten metal atoms and inert gas mixture of Nitrogen and argon atoms. The mixture is deposited such that a totally crystalline cluster-free amorphous Tungsten nitride alloy film is created. The crystalline cluster-free amorphous Tungsten nitride alloy film retains its crystalline cluster-free amorphous structure at most temperatures.

The method for fabricating a crystalline cluster-free amorphous Tungsten nitride alloy film includes sputtering a substrate using a Tungsten target. The method begins with placing a substrate in a sputtering chamber and placing an inorganic compound such as α-WNx (amorphous tungsten nitride) on a sputtering tool inside the sputtering chamber.

The method further comprises selecting a separation distance between the inorganic compound target and the maximized substrate to minimize adsorbed atom mobility of the crystalline cluster-free inorganic compound film deposited due to sputtering. The method further comprises adjusting a chamber pressure within an adequate range.

The method further comprises adjusting sputtering gas mixture ratio, wherein the sputtering gas mixture comprises inert gases such as of Argon and Nitrogen. The method further comprises adjusting sputtering power of the sputtering tool of 300 W of alternating current. The method may be cost effective.

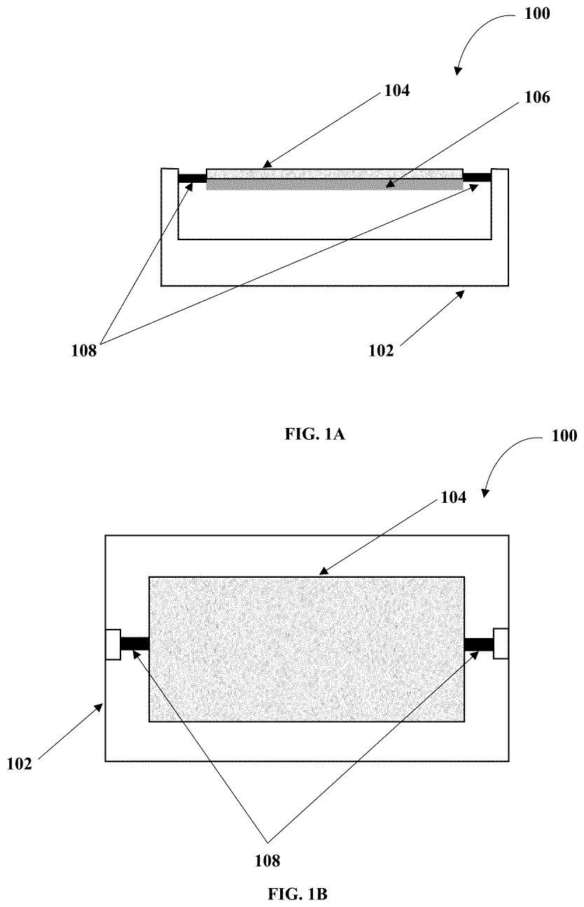

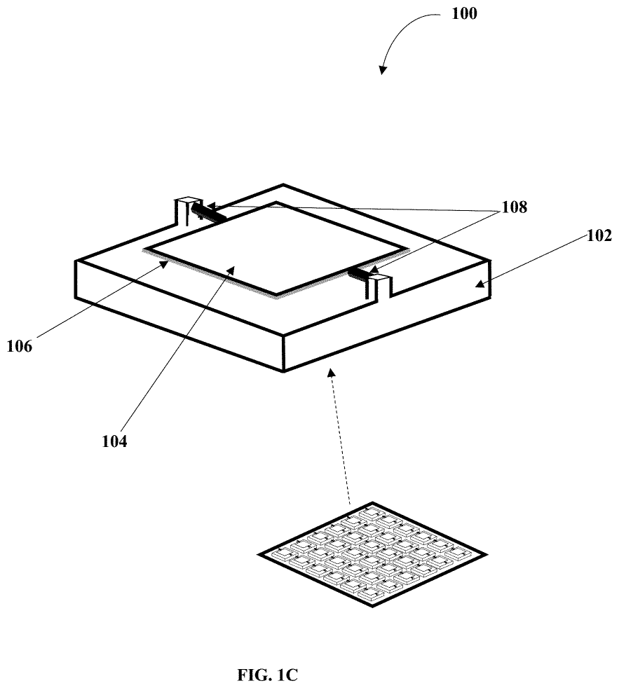

FIGS. 1A and 1B illustrate a side view and a top view of an exemplary MEMS-based inertial sensor in accordance with an embodiment of the present disclosure.

In an embodiment, a micro-electromechanical system (MEMS) based inertial sensor 100 with enhanced operational characteristics includes a film of an inorganic compound such as α-WNx 106. The α-WNx 106 film has properties such as high density of 17.5 g/cm3, which boosts its inertia force. Young's modulus (E) equals 300 GPa, which gives high retaining force and spring constant. Hardness (H) of 3 GPa provides a longer lifetime and low resistivity as a metal equal to 200 μΩcm for high Q factor.

In another embodiment, a crystalline cluster-free film of inorganic compound such as amorphous α-WNx 106 Tungsten nitride alloy is fabricated from a mixture of Tungsten metal atoms and inert gas mixture of Nitrogen and argon atoms. The mixture is deposited such that a totally crystalline cluster-free amorphous Tungsten nitride alloy film 106 is created. The crystalline cluster-free amorphous Tungsten nitride alloy film retains its crystalline cluster-free amorphous structure at most temperatures. These combined properties make the α-WNx 106 based inertial sensor 100 a high-quality sensor that matches tactical and navigation grades for low noise value and stable and high reproducibility properties.

In an embodiment, the inertial sensor 100 comprises a fixed plates and movable plates. The proof mass 104 is attached to a spring 108 which is configured to move along one direction and fixed outer plates. When an acceleration in the particular direction is applied, the mass will move and the capacitance between the plates and the mass will change. This change in capacitance will be measured and processed and will correspond to a particular acceleration value.

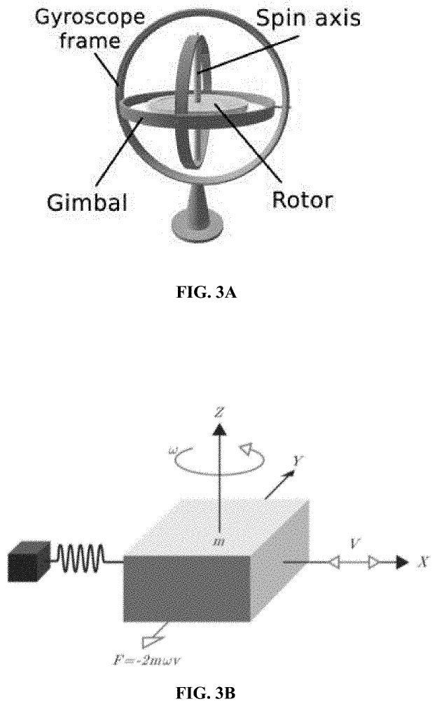

When the proof mass 104 is moving in a particular direction with a particular velocity and when an external angular rate is applied as shown in FIG. 3, a force will occur. The force causes perpendicular displacement of the proof mass 104. Similar to the accelerometer, this displacement will cause change in capacitance which will be measured and processed and will correspond to a particular angular rate. The proof mass 104 is constantly moving or oscillating. When the external angular rate is applied, a flexible part of the proof mass 104 moves and makes the perpendicular displacement.

In an embodiment, the proof mass 104 comprises a plurality of holes on its surface as shown in FIG. 1B. The inertial sensor 100 further includes an anchor 110. The inertial sensor further comprises ROIC control.

The α-WNx-based inertial sensor 100 includes the proof mass element 104 that moves in response to a motion. The deposition process of the α-WNx 106 is compatible with CMOS fabrication processes. The α-WNx 106 is a CMOS-compatible material. This makes the complete inertial sensor fabrication process 200 a single process flow, which may reduce costs. High conductivity provides low noise value and stable and high reproducibility properties for inertial sensor characteristics.

The α-WNx 106 dangles above the silicon substrate 102 and detects movement in response to motion of the proof mass 104. The inertial sensor 100 also includes electrode arms 108 coupled to the silicon substrate 102. This provides structural support for the α-WNx sensor 106 above the silicon substrate's surface acting as retaining springs. The electrode arms 108 further offer electrical connectivity for the inertial sensor 100.

In an embodiment, the electrode arms 108 may have elastic properties. In another embodiment, the electrode arms 108 may be made in a form of a spring to enable movement of the proof mass 104 for detecting motion.

FIGS. 1A and 1B depict inertial sensors 100 with only two electrodes 108. Some inertial sensors 100 may have more than two electrodes 108.

The α-WNx 106 is compatible with the CMOS fabrication processes. The inertial sensor 100 proof mass 104 may be carried out in the same fabrication that is used for manufacturing the ROIC (CMOS Fabrication).

The inertial sensor 100 has favorable operational characteristics due to its high density, connectivity, and value in Young's modulus. Additionally, fabrication of inertial sensor 100 based on α-WNx 106 metal is CMOS process compatible. These characteristics make the α-WNx 106 metal-based inertial sensors 100 favorable as compared to previous implementations of detectors.

In an embodiment, the amorphous tungsten nitride (α-WNx) 106 metal film is provided for an inertial sensor 100 and a manufacturing method 200. The α-WNx 106 material has properties with a high density of 17.5 g/cm3, which boosts its inertia force. Young's modulus (E) equals 300 GPa which gives high retaining force and spring constant. Hardness (H) of 3 GPa provides a longer lifetime and low resistivity as a metal equal to 200 μΩcm for high Q factor. These combined properties make the α-WNx 106 based inertial sensor 100 a high-quality sensor that matches tactical and navigation grades for a low noise value and stable and high reproducibility properties.

In an embodiment, α-WNx 106 is compatible with the CMOS fabrication process. The inertial sensor 100 fabrication may be carried out in the same fab manufacturing setting of the ROIC (CMOS Fab) as it is done for the polysilicon fabrication process. However, unlike polysilicon, α-WNx 106 material provides high-grade characteristics to the fabricated inertial sensor 100. This fabrication process 200 may reduce the cost of the navigation and tactical grade inertial sensor 100 on a significant scale and make them useful for numerous sensitive applications at a low cost.

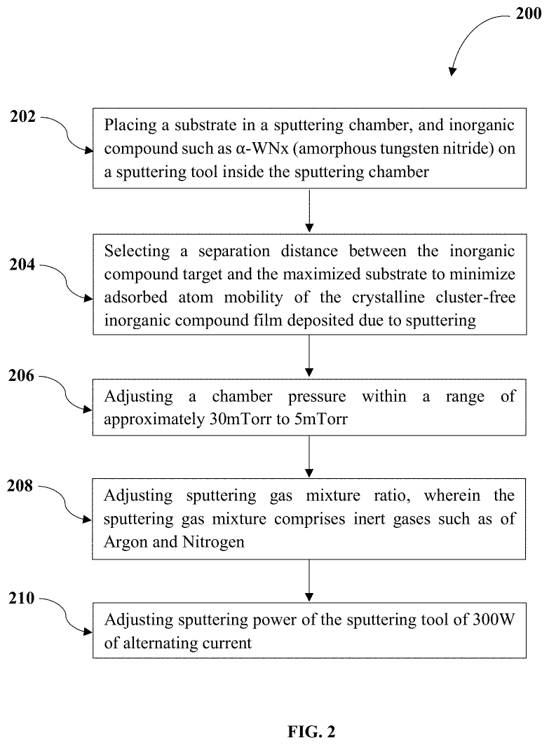

FIG. 2 illustrates an exemplary method 200 of fabricating a crystalline cluster-free inorganic compound such as α-WNx (amorphous tungsten nitride) film in accordance with an embodiment of the present invention. Beginning at step 202, a substrate is placed in a sputtering chamber and an inorganic compound such as α-WNx (amorphous tungsten nitride) on a sputtering tool inside the sputtering chamber.

At step 204, a separation distance between the inorganic compound target and the maximized substrate is selected to minimize adsorbed atom mobility of the crystalline cluster-free inorganic compound film deposited due to sputtering. At step 206 a chamber pressure is adjusted within a range of approximately 30 mTorr to 5 mTorr.

At step 208, sputtering gas mixture ratio is adjusted. The sputtering gas mixture comprises inert gases such as of Argon and Nitrogen. At step 210, sputtering power of the sputtering tool is adjusted to 300 W of alternating current.

The inertial sensor 100 and the fabrication method 200 involve a proof mass 104 element that moves in response to a motion. A α-WNx detector is dangled above a ROIC part of a silicon substrate 102. The proof mass 104 further includes spring arms 108 coupled to the silicon substrate 102 providing structural support for the dangling of α-WNx 106, further providing electrical connectivity for the complete inertial sensor 100.

A device which is used for navigation and angular velocity measurement is known as a gyroscope. A gyroscope made using MEMS technology may be known as MEMS gyroscope (as shown in FIG. 3). The MEMS gyroscope uses a small vibrating mechanism to detect changes in orientation. The gyroscope can measure rotational velocity of one, two or three direction axes. A 3-axis accelerometer is used to implement 3-axis gyroscope. There are various types of gyroscopes such as mechanical gyroscopes and MEMS gyroscopes as shown in FIG. 3.

Gyroscopes are inertial sensors that measure the angular rate of objects with respect to inertial reference frame. MEMS gyroscopes measures the angular rate by applying the theory of the Coriolis effect, which refers to the force of inertia that acts on objects in motion in relation to a rotating frame.

One may consider a mass suspended on springs, as illustrated in FIG. 3. This mass has a driving force on the x-axis causing it to oscillate rapidly in the x-axis. While in motion an angular velocity, w, is applied about the z-axis. This results in the mass experiencing a force in the y-axis as a result of the Coriolis force, and the resultant displacement is measured by a capacitive sensing structure.

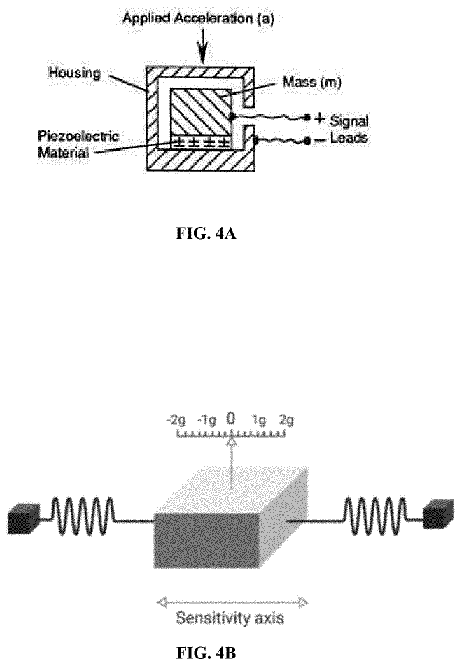

An accelerometer is the primary sensor responsible for measuring inertial acceleration, or the change in velocity over time, and can be found in a variety of different types, including mechanical accelerometers, quartz accelerometers, and MEMS accelerometers. A MEMS accelerometer is essentially a mass suspended by a spring, as illustrated in FIG. 4A. The mass is known as the proof mass and the direction that the mass is allowed to move is known as the sensitivity axis.

When an accelerometer is subjected to a linear acceleration along a sensitivity axis, the acceleration causes the proof mass to shift to one side, with the amount of deflection proportional to the acceleration.

One may further consider that the accelerometer is rotated such that the sensitivity axis is aligned with the gravity vector, as shown in FIG. 4B. In this case, gravity that acts on the proof mass is low due to micro size and weight. Because of this, the accelerometer measures only the linear acceleration due to motion as well as the pseudo-acceleration caused by gravity. The acceleration caused by gravity is referred to as a pseudo-acceleration as it does not actually result in a change in velocity or position.

The MEMS accelerometer is essentially a mass suspended by a spring, as illustrated in FIG. 4B. The mass is known as the proof mass and the direction that the mass is allowed to move is the sensitivity axis. When an accelerometer is subjected to a linear acceleration along the sensitivity axis, the acceleration causes the proof mass to shift to one side, with the amount of deflection proportional to the acceleration.

In an embodiment, a system for fabricating a crystalline film is provided comprising a sputtering chamber that receives placement of a substrate, receives placement of a Tungsten target, and receives configuration of a separation distance between the substrate and the Tungsten target. The system also receives adjustment of chamber pressure, receives selection of a gas mixture ratio, and receives selection of a sputtering power profile.

The chamber yields crystalline cluster-free amorphous Tungsten nitride alloy film. The chamber receives placement of the Tungsten target on a sputtering tool. The separation distance is configured to minimize adatom mobility of film produced. The chamber pressure is adjusted within a range of about 30 mTorr to about 5 mTorr, inclusive. The gas mixture ratio is a sputtering gas mixture ratio of Argon to Nitrogen. The sputtering power profile is for the sputtering tool. The power profile is 300 W of alternating current.

In another embodiment, a method for producing a film of inorganic compound comprising creating a first mixture comprising Nitrogen atoms and Argon atoms, creating a second mixture by combining the first mixture with Tungsten metal atoms, and depositing the second mixture to create Tungsten nitride alloy film. The alloy film is a crystalline film. The alloy film is cluster-free. The inorganic compound is an amorphous α-WNx Tungsten nitride alloy. The created Tungsten nitride alloy film retains an crystalline cluster-free amorphous structure at a plurality of temperatures. The film is at least partially produced in a sputtering chamber. Combined properties of the alloy film yield a sensor matching tactical and navigation grade for low noise value.

In yet another embodiment, a method for fabricating a crystalline compound is provided comprising placing a substrate in a sputtering chamber and placing an inorganic compound on a sputtering tool inside the sputtering chamber and selecting a separation distance between the inorganic compound and the maximized substrate. The method also comprises adjusting a chamber pressure within a range of approximately 30 mTorr to 5 mTorr, adjusting a ratio of a sputtering gas mixture, and adjusting sputtering power of the sputtering tool of 300 W of alternating current. The inorganic compound is α-WNx comprising amorphous tungsten nitride. The separation distance is selected to minimize adsorbed atom mobility of the crystalline cluster-free inorganic compound film deposited due to sputtering. The sputtering gas mixture comprises inert gases. The inert gases comprise at least one of Argon and Nitrogen.

What is claimed is:

1. A system for fabricating a crystalline film, comprising:
a sputtering chamber that:
receives placement of a substrate,
receives placement of a Tungsten target;
receives configuration of a separation distance between the substrate and the Tungsten target,
receives adjustment of chamber pressure,
receives selection of a gas mixture ratio, and
receives selection of a sputtering power profile.

2. The system of claim 1, wherein the chamber yields crystalline cluster-free amorphous Tungsten nitride alloy film.

3. The system of claim 1, wherein the chamber receives placement of the Tungsten target on a sputtering tool.

4. The system of claim 1, wherein the separation distance is configured to minimize adatom mobility of film produced.

5. The system of claim 1, wherein the chamber pressure is adjusted within a range of about 30 mTorr to about 5 mTorr, inclusive.

6. The system of claim 1, wherein the gas mixture ratio is a sputtering gas mixture ratio of Argon to Nitrogen.

7. The system of claim 1, wherein the sputtering power profile is for the sputtering tool.

8. The system of claim 1, wherein the power profile is 300 W of alternating current.

9. A method for producing a film of inorganic compound, comprising:
creating a first mixture comprising Nitrogen atoms and Argon atoms
creating a second mixture by combining the first mixture with Tungsten metal atoms; and
depositing the second mixture to create Tungsten nitride alloy film.

10. The method of claim 9, wherein the alloy film is a crystalline film.

11. The method of claim 9, wherein the alloy film is cluster-free.

12. The method of claim 9, wherein the inorganic compound is an amorphous α-WNx Tungsten nitride alloy.

13. The method of claim 9, wherein the created Tungsten nitride alloy film retains an crystalline cluster-free amorphous structure at a plurality of temperatures.

14. The method of claim 9, wherein the film is at least partially produced in a sputtering chamber.

15. The method of claim 9, wherein combined properties of the alloy film yield a sensor matching tactical and navigation grade for low noise value.

16. A method for fabricating a crystalline compound, comprising:
placing a substrate in a sputtering chamber and placing an inorganic compound on a sputtering tool inside the sputtering chamber;
selecting a separation distance between the inorganic compound and the maximized substrate;
adjusting a chamber pressure within a range of approximately 30 mTorr to 5 mTorr;
adjusting a ratio of a sputtering gas mixture; and
adjusting sputtering power of the sputtering tool of 300 W of alternating current.

17. The method of claim 16, wherein the inorganic compound is α-WNx comprising amorphous tungsten nitride.

18. The method of claim 16, wherein the separation distance is selected to minimize adsorbed atom mobility of the crystalline cluster-free inorganic compound film deposited due to sputtering

19. The method of claim 16, wherein the sputtering gas mixture comprises inert gases.

20. The method of claim 16, wherein the inert gases comprise at least one of Argon and Nitrogen.
